(19) United States
(12) Patent Application Publication
(10) Pub. No.: US 2002/0160588 A1
(43) Pub. Date: Oct. 31, 2002

(54) METHOD OF FORMING A JUNCTION IN SEMICONDUCTOR DEVICE USING HALO IMPLANT PROCESSING

(76) Inventors: Jeong Soo Kim, Kyoungki-do (KR); Sang Ho Sohn, Daegu (KR)

Correspondence Address: BIRCH STEWART KOLASCH & BIRCH, PO BOX 747, FALLS CHURCH, VA, 22040-0747, US

(21) Appl. No.: 09/998,134

(22) Filed: Dec. 3, 2001

(30) Foreign Application Priority Data
Apr. 30, 2001 (KR) 2001-23405

(51) Int. Cl. H01L 21/8238; H01L 21/425

(52) U.S. Cl. 438/526; 438/525; 438/527

(57) ABSTRACT

A method for forming a junction in a semiconductor device including the steps of: forming a photoresist film pattern on a semiconductor substrate excluding a halo implant region; performing a first halo implant process on the halo implant region of the semiconductor substrate by using a tilt angle of about 45°; and performing a second halo implant process on the halo implant region of the semiconductor substrate by using a tilt angle of about 0°.

### BACKGROUND OF THE INVENTION

1. Field of the Invention

The present invention relates to a method for fabricating a semiconductor device, and in particular, to a method for forming a junction in a semiconductor device according to a halo implant process.

2. Description of the Background Art

In a conventional halo implant process, in order to perform an ion implant process at a tilt angle of 45° below a gate, the ion implant process is started in a fault zone of a wafer, and performed completely four times by moving at a twist angle of 90° every time.

However, the ion implant process is not evenly performed due to the height of a gate or photoresist film. Such a problem becomes more serious in a cell region where the photoresist film is not sufficiently isolated from an adjacent active region due to a tight design rule.

The foregoing problem of the conventional halo implant process will now be explained in more detail with reference to FIG. 1.

FIG. 1 is a layout view illustrating a semiconductor device and four halo implant processes in a conventional method for forming a junction in the semiconductor device.

Referring to FIG. 1, a semiconductor substrate is divided into PMOS regions 2, 6 and NMOS region 4. In a case where the PMOS regions are coated with a photoresist film pattern (as in this case) , the halo implant process is carried out on the NMOS region 4.

Here, the halo implant process is performed four times. That is, the halo implant process is carried out two times from the direction of the two sides where the photoresist film is coated, and carried out two times on the other two sides where the photoresist film is not coated. More specifically, as shown in FIG. 1, a first ion implant 8 occurs from the direction of the lower side of the uncoated NMOS region 4, and a third ion implant 10 occurs from the direction of the upper portion of the uncoated NMOS region 4. Also, a second ion implant 5 and fourth ion implant 1 occur from the directions of the PMOS regions 2 and 6, respectively. Therefore, the ion implant process is normally performed once in all respective regions below a gate 3 by the four tilt ion implant processes.

However, in spite of the four ion implant processes, the ion implant number is different in each junction. A height of the photoresist film is 1.1 μm. Accordingly, in the right and left ion implant processes (for example, second and fourth ion implant processes 5, 1), one time ion implant process cannot be performed on the active region within 0.8 μm distance from the photoresist film due to the height of the photoresist film. That is, a halo implant shadow effect is generated once due to the height of the photoresist film. As a result, the ion implant process on the junction is reduced to three times. Nevertheless, the three ion implant processes are homogeneously performed.

As illustrated in FIG. 1, the ion implant process is performed three times on the normal region indicated by B. However, the ion implant process is carried out in the region A merely two times because the shadow effect is generated due to the gate 3 in the second ion implant process.

When a height of the gate 3 is about 0.2 μm, the shadow effect is generated to the extent of 0.2 μm of the junction.

That is, the ion implant process is performed on the first junction region A two times, and performed on the second junction region B three times. Therefore, a threshold voltage Vt is moved due to the heterogeneous junction ion implant process.

### SUMMARY OF THE INVENTION

Therefore, it is a primary object of the present invention to provide a method for forming a junction in a semiconductor device which can maintain homogeneous doping of the junction, by preventing a shadow effect in the junction formation using a halo implant process.

Another object of the present invention is to provide a method for forming a junction in a semiconductor device which can improve a yield, by preventing movement of a threshold voltage by maintaining homogeneous doping of the junction.

In order to achieve the above-described objects of the present invention, there is provided a method for forming a junction in a semiconductor device, including the steps of: forming a photoresist film pattern on a semiconductor substrate excluding a first region; performing a first halo implant process on the first region of the semiconductor substrate by using a tilt angle of about 45°; and performing a second halo implant process on the first region of the semiconductor substrate by using a tilt angle of about 0°.

According to another aspect of the present invention, a method for forming a junction in a semiconductor device includes the steps of: providing a semiconductor substrate divided into a first conductive type MOS region and a second conductive type MOS region; forming a photoresist film pattern in the second conductive type MOS region of the semiconductor substrate; performing first and second halo implant processes on the first conductive type MOS region of the semiconductor substrate at twist angles of about 0° and 180° , respectively, by using a tilt angle of about 45° ; and performing a third halo implant process on the first conductive type MOS region of the semiconductor substrate, by using a tilt angle of about 0°.

### BRIEF DESCRIPTION OF THE DRAWINGS

The present invention will become better understood with reference to the accompanying drawings which are given only by way of illustration and thus are not limitative of the present invention, wherein:

FIG. 1 depicts a semiconductor device and a plurality of halo implant processes, according to a conventional method for forming a junction in the semiconductor device;

FIG. 2 depicts a semiconductor device with the halo implant process, of one method for forming a junction in the semiconductor device in accordance with the present invention;

FIG. 3 is a perspective view depicting a semiconductor device and the halo implant process of one method for forming the junction in the semiconductor device in accordance with the present invention; and

FIG. 4 depicts a cross-sectional view of the semiconductor device when the first halo implant process is performed according to one method of the present invention.

FIG. 5 depicts a cross-sectional view of the semiconductor device when the second halo implant process is performed according to one method of the present invention.

FIG. 6 depicts a cross-sectional view of the semiconductor device when the third halo implant process is performed according to one method of the present invention.

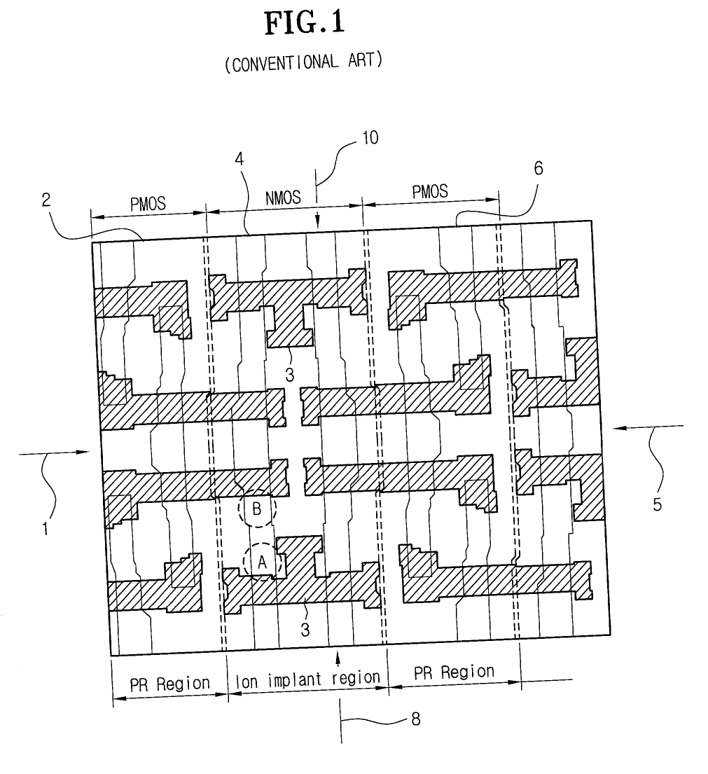

### DETAILED DESCRIPTION OF THE PREFERRED EMBODIMENTS

A method for forming a junction in a semiconductor device in accordance with a preferred embodiment of the present invention will now be described in detail with reference to the accompanying drawings.

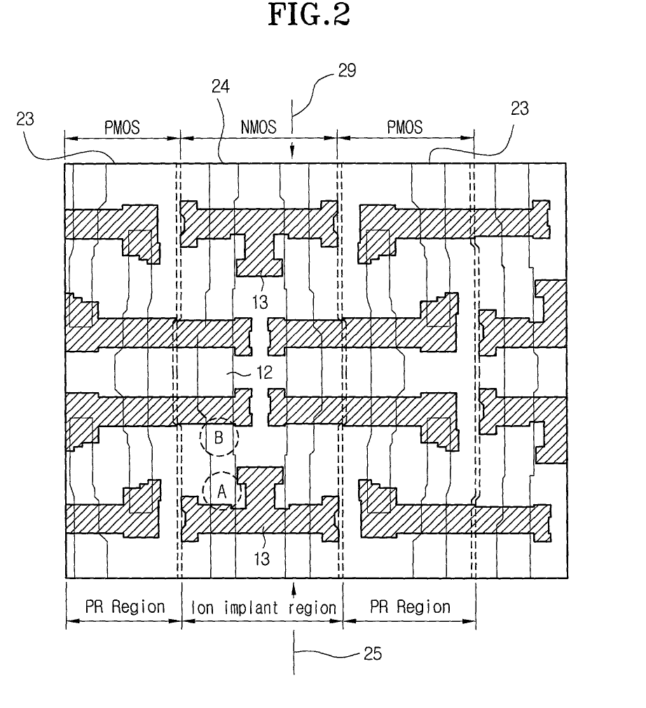

FIG. 2 is a layout view illustrating the semiconductor device to explain a halo implant process in accordance with the present invention.

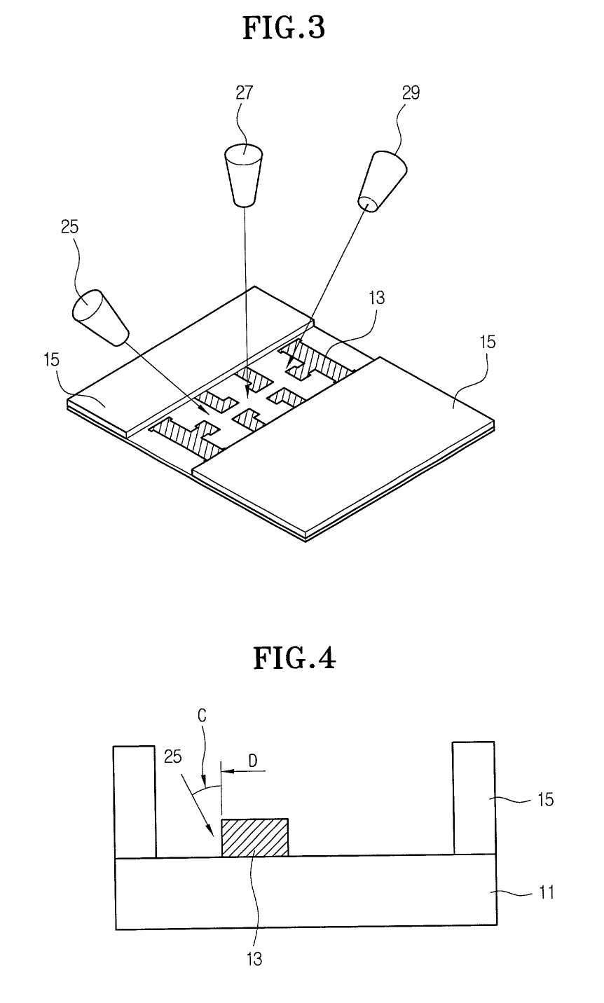

FIG. 3 is a perspective view illustrating the semiconductor device using the halo implant process in accordance with the present invention.

FIGS. 4 through 6 are cross-sectional views illustrating the semiconductor device where the first to third halo implant processes are performed in accordance with the present invention.

Referring to FIG. 2, a plurality of active regions 12 are defined by an element isolating film (not shown) on a semiconductor substrate 11 divided into an NMOS region 21 and a PMOS region 23, and a plurality of gate patterns 13 are formed on the semiconductor substrate 11, crossing the plurality of active regions 12. First and second ion implants 25 and 29 are also depicted for the NMOS ion implant region 21. In addition, impurities having different conductive types are halo-implanted on the active regions 12 in the NMOS region 21 and PMOS regions 23.

In the halo implant process of the present invention, a halo implant process using a tilt angle of 45° is performed twice, and the halo implant process using a tilt angle of 0° is performed once.

In more detail, when the halo implant process is carried out on the active regions of the NMOS region 21, the PMOS region 23 is coated with a photoresist film pattern 15 which is a halo implant mask for preventing ion implantation.

As illustrated in FIGS. 3 and 4, in order to perform the ion implantation below gate patterns 13, a first halo implant process 25 is performed at a tilt angle C of approximately 45° at one side of the NMOS region 21 in parallel to the photoresist film pattern 15. The tilt angle C represents the degree of variation of the ion implantation from a line-D drawn perpendicular to the substrate. Here, the first halo implant process 25 is performed with an energy of 20 KeV and a dose of 4.0×10¹².

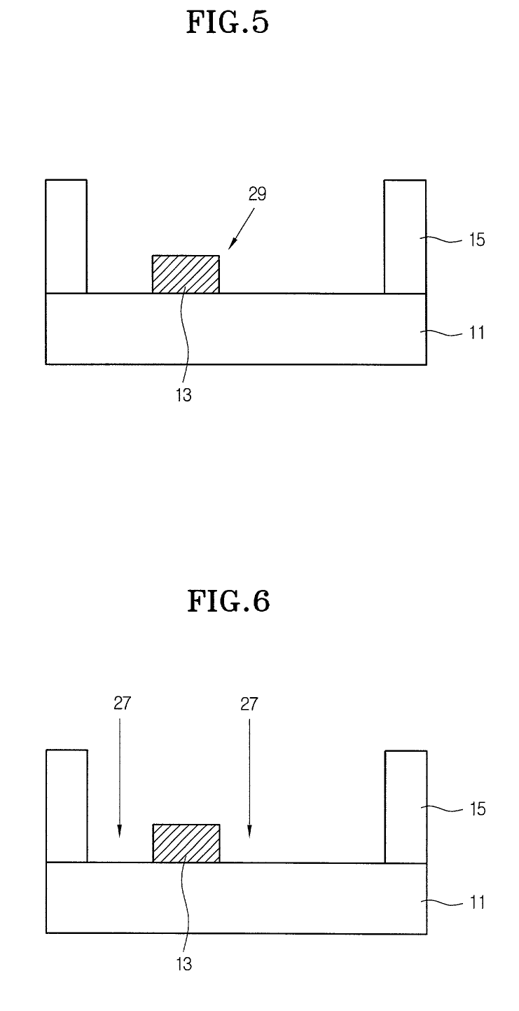

As depicted in FIGS. 3 and 5, a second halo implant process 29 is performed at a tilt angle of approximately 45° at the other side of the NMOS region. At this time, the second halo implant process 29 is carried out in the same manner as the first halo implant process 25.

In order to prevent heterogeneous doping of the junction due to the halo implant process, the first halo implant process 25 is performed at a twist angle of approximately 0° and the second halo implant process 29 is performed at a twist angle of approximately 180°.

As shown in FIGS. 3 and 6, a third halo implant process 27 is vertically performed on the semiconductor substrate 11 at a tilt angle of approximately 0°. Here, the third halo implant process 27 is performed with an energy of 16 KeV and a dose of 4×10¹².

In addition, the third halo implant process 27 using a tilt angle of 0° must be carried out by considering an impurity ion depth in the halo implant processes using a tilt angle of 45°. That is, the third halo implant process 27 should not be performed with the same energy as the first and second halo implant processes 25, 29.

Accordingly, the ion implant process is performed three times on regions A, B of FIG. 2 through the first to third halo implant processes 25, 29, 27.

As discussed earlier, the method for forming the junction of the semiconductor device in accordance with the present invention has the following advantages:

The halo implant process is performed at a tilt angle of 0°, and thus not influenced by a height of the photoresist film pattern mask or gate. Therefore, the shadow effect is not generated due to the height of the mask or gate, which results in homogeneous doping of the junction.

Moreover, the homogeneous doping prevents movement of the threshold voltage Vt, thereby improving a yield of the semiconductor device.

In addition, the halo implant process is stably performed even with a tight design rule resulting from miniaturization of a chip.

It is noted that the energies and dosage levels of the first-third ion implant processes may change according to the needs of the specific applications. Additionally, other methods according to this invention could also be performed including applying the first through third halo implants on the PMOS regions while the NMOS regions are covered with photoresist.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. A method for forming a junction in a semiconductor device, comprising the steps of:
forming a photoresist film pattern on a semiconductor substrate excluding a first region;
performing a first halo implant process on the first region of the semiconductor substrate by using a tilt angle of about 45°; and
performing a second halo implant process on the first region of the semiconductor substrate by using a tilt angle of about 0°.

2. The method according to claim 1, wherein the first halo implant process is performed with an energy of 20KeV and a dose of 8.0×10¹².

3. The method according to claim 1, wherein the first halo implant process is performed twice at twist angles of about 0° and 180°.

4. The method according to claim 1, wherein the second halo implant process is performed only once at a tilt angle of about 0°.

5. The method according to claim 1, wherein the second halo implant process is performed with an energy of 16 KeV and a dose of 4×10¹².

6. The method according to claim 1, wherein the photoresist film pattern is formed on a PMOS region, and the first region is an NMOS region.

7. The method according to claim 1, wherein the photoresist film pattern is formed on an NMOS region, and the first region is a PMOS region.

8. A method for forming a junction in a semiconductor device, comprising the steps of:
providing a semiconductor substrate divided into a first conductive type MOS region and a second conductive type MOS region;
forming a photoresist film pattern on the second conductive type MOS region;
performing first and second halo implant processes on the first conductive type MOS region at about a 45° tilt angle and at twist angles of about 0° and 180°, respectively; and
performing a third halo implant process on the first conductive type MOS region, by using a tilt angle of about 0°.

9. The method according to claim 8, wherein the first halo implant process is performed with an energy of 20 KeV and a dose of 4.0×10¹².

10. The method according to claim 8, wherein the second halo implant process is performed with an energy of 20 KeV and a dose of 4.0×10¹².

11. The method according to claim 8, wherein the third halo implant process is performed with an energy of 16 KeV and a dose of 4×10².

12. The method according to claim 8, wherein the first conductive type MOS region is an NMOS region, and the second conductive type MOS region is a PMOS region.

13. The method according to claim 8, wherein the first conductive type MOS region is a PMOS region, and the second conductive type MOS region is an NMOS region.
